(19) United States
(12) Patent Application Publication
(10) Pub. No.: US 2006/0127700 A1
(43) Pub. Date: Jun. 15, 2006

(54) Coating film for inhibiting coke formation in ethylene dichloride pyrolysis cracker and method of producing the same

(76) Inventors: Donghyun Jo, Daejeon-city (KR); Jongwook Bae, Daejeon-city (KR); Juyoul Kim, Hwaseong-city (KR); Sung Won Kim, Daejeon-city (KR); Byungchul Oh, Daejeon-city (KR); Seung Back Ha, Hanam-city (KR)

Correspondence Address: CANTOR COLBURN, LLP, 55 GRIFFIN ROAD SOUTH, BLOOMFIELD, CT, 06002, US

(21) Appl. No.: 11/301,176

(22) Filed: Dec. 12, 2005

(30) Foreign Application Priority Data
Dec. 10, 2004 (KR) 10-2004-0104045

(51) Int. Cl. B05D 7/22; C23C 16/00; B05D 1/02; B32B 15/04; B32B 9/04

(52) U.S. Cl. 428/704; 427/421.1; 427/248.1; 427/233; 428/457

(57) ABSTRACT

Provided is a coating film that inhibits the formation of coke in an ethylene dichloride to a vinyl chloride monomer pyrolysis cracker and a method of producing the coating film. The coke formation, which occurs during a pyrolysis reaction, is inhibited by coating a boron compound on a heat-transfer surface of the cracker. As a result, the amount of coke generated when a coke formation-inhibiting material is coated is decreased by 50% or greater than that when the coke formation-inhibiting material is not coated. In this case, however, the ethylene chloride conversion and the selectivity to a vinyl chloride monomer during the pyrolysis reaction are not affected. Accordingly, the efficiency of the pyrolysis cracker can be maximized.

### CROSS-REFERENCE TO RELATED PATENT APPLICATIONS

This application claims the benefit of Korean Patent Application No. 10-2004-0104045, filed on Dec. 10, 2004 in the Korean Intellectual Property Office, the disclosure of which is incorporated herein in its entirety by reference.

### BACKGROUND OF THE INVENTION

1. Field of the Invention

The present invention relates to a coating film for inhibiting the formation of coke in a pyrolysis cracker and a method of producing the same, and more particularly, to a coating film that inhibits the formation of coke in an ethylene dichloride to vinyl chloride monomer pyrolysis cracker and a method of producing the same.

2. Description of the Related Art

Pyrolysis crackers are typically operated at temperatures of from about 400° C. to about 600° C., at gauge pressures of from about 1.4 Mpa to about 3.0 Mpa and with a residence time from about 2 seconds to about 60 seconds. An ethylene dichloride (EDC) conversion per pass through a pyrolysis cracker is normally maintained around 50-70% with a selectivity of 96-99% to a vinyl chloride product. In this case, vinyl chloride monomer (VCM) and HCl are produced. By-products from the pyrolysis process range from the very lights, such as methane, acetylene, ethylene, and methyl chloride, to the heavies, such as carbon tetrachloride, trichloroethane and solid carbonaceous material. Solid carbonaceous material is usually referred to as coke, and coke brings about problems.

Higher conversion in the pyrolysis process is, in most cases, desired. However, increasing cracking temperature, pressure, and other conditions beyond conventional operating conditions generally leads to only a small increase in the EDC conversion at the expense of the-selectivity to a vinyl chloride product. Furthermore, any outstanding increase in cracking temperature and pressure causes a drastic increase in coke formation.

Such coke formation in the pyrolysis cracker results in many problems. For example, coke formation inhibits the heat transfer to reactants in the pyrolysis cracker such that combustion energy is only partially transferred to reactants and the remaining combustion energy is lost to the surroundings. Therefore, the pyrolysis cracker is required to be heated at a higher temperature to maintain the energy in the cracker at a proper level. Such heating requires more fuel and the lifetime of the alloy of the cracker is reduced. Conventionally, high temperatures cause erosion or corrosion of the walls of a cracker.

Meanwhile, the coke formed in the cracker reduces the width of the reaction path of EDC, thereby causing the pressure to drop with more depth when EDC passes through the cracker. As a result, more energy is required to compress the stream of a product, such as vinyl chloride (VC), in a downstream of the process. In addition, the coke reduces the effective inner volume of the cracker, which decreases the yield of the product and affects the selectivity of the reaction. Accordingly, more EDC is required to attain a desired amount of VC.

The coke formation also causes fouling of a heat exchanger and a transfer line exchanger (TLE.) A heat exchanger and a TLE remove as much thermal energy as possible from high-temperature products to stop any product degradation. However, when coke is formed in the heat exchanger and the TLE, heat transfer is inhibited. As a result, in the TLE, an increase of the pressure of gas existing in other transfer lines decreases, and in the heat exchanger, a pressure decrease of a product stream more increases.

Accordingly, coke is periodically removed. Known methods for the removal of coke from pyrolysis crackers include controlled combustion or mechanical cleaning, or a combination of both methods. In the combustion process, a mixture of steam and air using various steam/air ratios is admitted to the pyrolysis furnace at an elevated temperature, and the coke in the cracker is burnt out under a controlled condition. This process is conventionally referred to as hot decoke. For the mechanical cleaning, coke is physically chipped off the pyrolysis cracker inner surface and removed from the cracker. Both cracking and the hot decoke operations expose the pyrolysis cracker to a cycle between HCl and chlorinated hydrocarbon-rich reducing environment and an oxygen-rich oxidizing environment at elevated temperatures, which causes corrosion and degradation of the pyrolysis cracker and shortens the cracker lifetime.

The pyrolysis cracker is periodically decoked every 6 to 12 months, according to purity of reactant EDC and operating conditions, such as reaction temperature, reaction pressure, a feed speed of EDC, and a cracking depth. In particular, when a heat exchanger is installed in a high-temperature EDC pyrolysis cracker to efficiently use the energy at a cracker outlet, formation of a coke precursor results in a dramatic drop of temperature in the cracker and thus coke is more quickly deposited on the inner walls of the heat exchanger, thereby shortening the removal cycle.

Conventional methods of inhibiting coke formation will now be described.

U.S. Pat. No. 6,228,253 teaches a method of coating Groups 1A and 2A metal salts on the inner walls of a cracker tube to inhibit coke formation. This method is advantageous in that there is no need to stop the process to remove the coke. However, this method can only be used for a conventional hydrocarbon pyrolysis reaction.

U.S. Pat. No. 3,896,182 teaches a method of inhibiting coke formation by lowering the oxygen content in the EDC feed.

U.S. Pat. No. 6,454,995 teaches a method of applying a phosphine-based compound (tributyl phosphine, triphenyl phosphine, or the like) to an EDC pyrolysis cracker. This method is not so effective on inhibiting coke formation and low reproducibility. In addition, since the phosphine-based compound is expensive, the method is not cost effective.

Coke formation in pylolysis crackers continues to be undesirable and thus effective alternative methods to more efficiently inhibit the formation of coke during a pyrolysis process are always required.

### SUMMARY OF THE INVENTION

The present invention provides a coating film that can efficiently inhibit the formation of coke at a heat-transfer surface of an ethylene dichloride (EDC) pyrolysis cracker.

The present invention also provides a method of forming the coating film.

The present invention also provides an efficient EDC pyrolysis cracker in which coke formation is inhibited.

According to an aspect of the present invention, there is provided a coating film containing a boron compound in an ethylene dichloride pyrolysis cracker.

According to another aspect of the present invention, there is provided a method of producing a coating film by, for example, spraying.

According to yet another aspect of the present invention, there is provided an ethylene dichloride pyrolysis cracker including the coating film.

According to a coating film and a method of producing the same, coke formation in an ethylene dichloride pyrolysis cracker is effectively inhibited and the ethylene dichloride conversion can be additionally increased. As a result, the decoking cycle of the cracker can be increased 2 times or greater and the production efficiency of a vinyl chloride monomer can be increased. In addition, the coke formation-inhibiting material has a great practical value because it can be collected for re-use and is inexpensive.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view of a pyrolysis cracker according to an embodiment of the present invention;

FIG. 2 is a view illustrating a transfer process of a carrier gas and a coating solution according to an embodiment of the present invention;

FIG. 3 is a view schematically illustrating a spray-nozzle type spraying process according to an embodiment of the present invention;

FIG. 4A is an image of a bare tube that was not pre-treated;

FIG. 4B is an image of a tube that was pre-treated using a buffing method;

FIG. 4C is an image of a tube that was pre-treated using a buffing method and an electronic polishing;

FIG. 5A is a scanning electron microscope (SEM) image of a SUS-316 sample that is treated at 600° C. using air;

FIG. 5B is a SEM image of a sample that is treated at 600° C. using air and steam;

FIG. 5C is a SEM image of a sample that is treated at 600° C. using a boron compound;

FIG. 6A shows an ESCA 2D depth profile of a sample measured 2 hours after a coating treatment; and

FIG. 6B shows an ESCA 2D depth profile of a sample measured 4 hours after a coating treatment.

### DETAILED DESCRIPTION OF THE INVENTION

Hereinafter, the present invention will be described in detail by explaining embodiments of the invention with reference to the attached drawings.

Inventors of the present invention found the fact that when a coating film containing a boron-based compound is formed in an ethylene dichloride (EDC) pyrolysis cracker, coke formation is effectively inhibited.

In an EDC pyrolysis cracker, coke can be formed in a gas phase, which is a tar-typed coke, or formed through catalysis with metal existing at the surface of the cracker. The coke that is formed through catalysis comprises the majority of the coke and needs to be removed. Accordingly, the catalysis between the metal and EDC can be inhibited by forming a coating film on the cracker.

A coating film may be formed of a material that has excellent heat conductivity, is inert with EDC, and is not modified at high temperature.

The coating film may be mainly formed of an inorganic material. Conventional organic materials and metals are unsuitable for the coating film because they are affected by temperature and catalysis. As for an inorganic material having many of these properties, an amorphous solid, such as glass, is more suitable than a crystalline solid because amorphous solids are more flexible with respect to temperature.

A coating film according to an embodiment of the present invention may contain a boron compound in the EDC pyrolysis cracker. In the coating film, the boron compound may contain a boron compound represented by Formula 1; or a hydrate, oxide, pyrolysis product, oligomer, or sintered product thereof:
(M)ₐ(B)_{b}(X)_{c} Formula 1
where M is a Groups IA or IIA metal, or hydrogen;

B is boron;

a and c are each independently an integer of 0-12 where 3≦a+c<24;

b is an integer of 1-10;

when a=0, X is oxygen, hydrogen, halogen, hydroxy, alkoxy, aryloxy, alkyl, aryl, alkylaryl, or arylalkyl; and

when a≧1, X is oxygen.

In Formula 1, halogen is F, Cl, Br or I; alkyl is a C1-C20 saturated hydrocarbon; aryl is a C6-C20 aromatic mono-ring or multiple-ring system radical; alkylaryl, such as a methyl phenyl group, is an aryl having at least one alkyl substituent; arylalkyl, such as a benzyl group, is alkyl having at least one aryl substituent; alkoxy is a C1-C20 saturated hydrocarbon having an oxygen atom directly connected to boron; and aryloxy is a C6-C20 aromatic mono-ring or multiple-ring system radical having an oxygen atom directly connected to boron.

The boron compound represented by Formula 1 may be H₃BO₃, B₂O₃, a boron halide-based compound or a borate-based compound. For example, the coating film may be formed of H₃BO₃; B₂O₃; a boron halide-based compound, such as BF₃, BCl₃, BBr₃, or Bl₃; or a borate-based compound, such as BNaO₃, B₂BaO₄, B₄K₂O₇, or B₄Li₂O₇.

It is assumed that the coating film formed of such boron compounds in the pyrolysis cracker may be glassy. The average thickness of the coating film may range from 0.01 μm to 10 μm. When the thickness of the coating film is less than 0.01 μm, the reduction of coke formation due to the coating is small. When the thickness of the coating film is greater than 10 μm, the reduction of coke formation is small and more by-products are formed.

The coating film may contain, in addition to the boron compound, a phosphorus compound. In the present invention, the phosphorus compound is a phosphine-based compound. The phosphine-based compound may be a phosphine substituted with hydrogen or any compound where phosphorus is connected to other functional groups. In the boron-phosphine mixture, the amount of the phosphine-based compound may be in the range of 5-50% by weight. When the phosphine-based compound is less than 5% by weight, the reduction of coke formation is small, and when the phosphine-based compound is greater than 50% by weight, more by-products are generated and the pyrolysis process is not cost effective.

The phosphorus compound used may be a phosphine-based compound represented by Formula 2; or a hydrate, oxide, pyrolysis product, oligomer or sintered product thereof.
(P)ₐ(R)_{b} Formula 2
where P is phosphorus;

a is an integer of 1-10;

b is an integer of 3-10; and

R is oxygen, halogen, hydroxy, alkoxy, aryloxy, alkyl, aryl, alkylaryl, or arylalkyl.

Since the coating film may be more effective when the surface of a cracker tube is clean, a coke formation-inhibiting material may be applied after coke is completely removed.

A method of forming the coating film may include at least one method selected from the group consisting of a spraying method, an impregnating method, a painting method, an electric plating method, a physical vapor depositing method, and a chemical vapor depositing method.

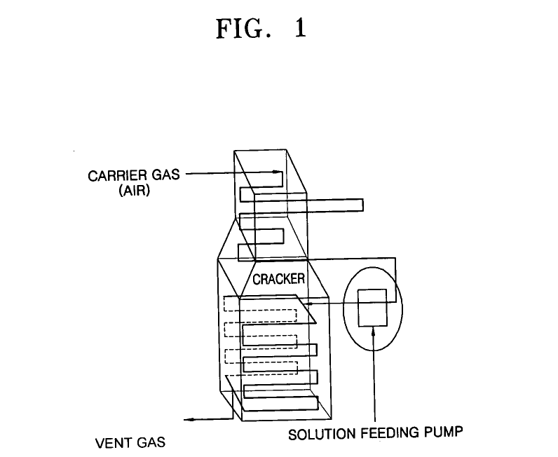

For example, the coating film may be formed using a spray-nozzle method in which a boron compound is mixed with a carrier gas and the resulting mixture is supplied to the inside of the cracker. The spray-nozzle method is schematically illustrated in FIGS. 1 through 3.

Referring to FIG. 1, a carrier gas is supplied to a cracker and moves along a coil. In the middle of the coil, a coating solution is supplied by pumps and is mixed with the carrier gas. The mixture of the carrier gas and the coating solution passes through the cracker and is then discharged.

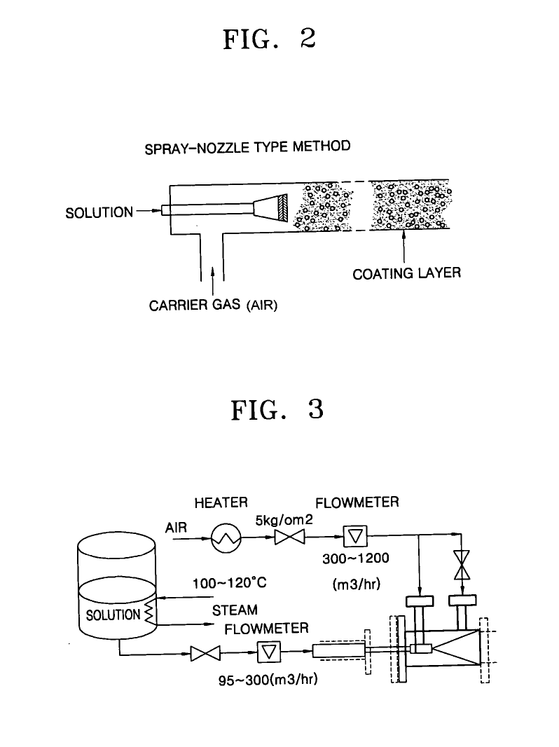

Referring to FIG. 2, the carrier gas is heated by a heater and supplied to an outside of a nozzle at a speed of 390-1200 L/hr to form a gas stream. The coating solution is heated by steam and then supplied to the nozzle at a speed of 95-300 L/hr.

Referring to FIG. 3, the coating solution is supplied to the nozzle under a constant pressure. The coating solution is divided into micro particles by the nozzle and then sprayed. The sprayed micro particles of the coating solution are mixed with the carrier gas to form a stream, which is deposited on an inner wall of the cracker. Since the divided solution particles are of micrometer dimensions, they can be dried in a very short time.

On the other hand, a method of coating the inside of a cracker to reduce coke formation in the EDC pyrolysis cracker includes: feeding a boron compound through a first tube; feeding a carrier gas through a second tube; mixing the boron compound and a carrier gas at the junction of the first and second tubes; and spraying the mixture of the boron compound and the carrier gas using a spray nozzle on the inside of the cracker.

In this coating method, the boron compound may be supplied in an aqueous liquid form with a concentration of 0.5-10% by weights. In order to reduce the coating time, a saturated boron compound prepared by saturating water with the boron compound can be used for the coating process. In this case, fuel consumption is low. However, the concentration of the boron compound solution may be less than 10% by weight to prevent an excessive coating on the inside of the cracker tube. On the other hand, when the concentration of the boron compound solution is less than 0.5% by weight, the coating time increases and fuel consumption increases.

The amount of the coke formation-inhibiting material that is coated on the inside of the cracker tube may be 1% by weight or less of the total amount of the coke formation-inhibiting material supplied. When the total coated amount is greater than 1% by weight, the inhibition effect on coke formation may substantially decrease.

A coke formation-inhibiting material that is not coated can be collected at an end of the cracker for re-use. When the amount of the coke formation inhibiting material that is coated is 1% by weight or less, the coke formation is reduced, the selectivity to a VCM and the EDC conversion may increase.

In the coating method, the carrier gas may include at least one gas selected from inert gas and air. For example, the carrier gas may be an oxygen-containing air that can oxidize the boron compound.

In the mixture of the carrier gas and the boron compound used for the coating method, the mole ratio of the carrier gas to the boron compound is in the range of 0.5-10, and may be 2-7. When the mole ratio of the carrier gas to the boron compound is less than 0.5, the boron compound is incompletely oxidized and the inhibition effect on coke formation decreases. When the mole ratio of the carrier gas to the boron compound is greater than 10, excessive oxidation occurs in the cracker tube and coke formation increases.

In the coating method, the mixture of the boron compound and the carrier gas may be supplied to the inside of the cracker at a supply temperature of 200-400° C. for 1-24 hours.

When the supply temperature is less than 200° C., an inlet of the cracker is plugged. When the supply temperature is greater than 400° C., the fuel consumption increases. When the supply time is less than 1 hour, the inside of the cracker tube may be coated locally. When the supply time is greater than 24 hours, there is excessive fuel consumption.

In the coating method, the residence time of the mixture of the boron compound and the carrier gas is in the range of 2-200 sec, and preferably, 5-100 sec. However, when the inside diameter of the cracker is small, the residence time may be in the range of 2-50 sec. When the residence time is less than 2 sec, the inside of the cracker is incompletely coated. When the residence time is greater than 200 sec, excessive coating may occur or the coating may not be homogeneous.

The temperature of the inside of the cracker to which the mixture of the boron compound and the carrier gas is supplied may be in the range of 400-800° C., and preferably, 450-650° C. When the temperature of the inside of the cracker is less than 400° C., it is difficult to oxidize the coating material and the amount of coke formed is not reduced significantly. When the temperature of the inside of the cracker is greater than 800° C., the lifetime of the cracker decreases, a material that forms the cracker is thermally modified, and fuel consumption increases.

In a coating method according to an embodiment of the present invention, the mixture of a carrier gas and a boron compound in a mole ratio of 2-7 is supplied to a cracker, the inside of which has a temperature of 450-650° C., at a supply temperature of 200-400° C., for 1-24 hours. In this case, the residence time of the mixture is in the range of 5-100 sec.

In a coating method according to an embodiment of the present invention, a carrier gas is mixed with a boron compound in a mole ratio of 2-5 and the mixture is supplied to a cracker, the inside of which has a temperature of 550-650° C., at a supply temperature of 200-400° C., for 5-15 hours. In this case, the residence time of the mixture is in the range of 5-50 sec.

The coating may be heavily dependent on the state of the inside of the cracker. For example, a more homogenous inside of the cracker results in more homogenous coating and less coke formation.

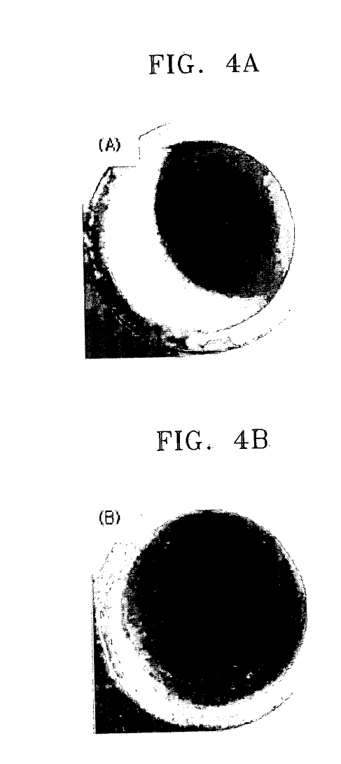

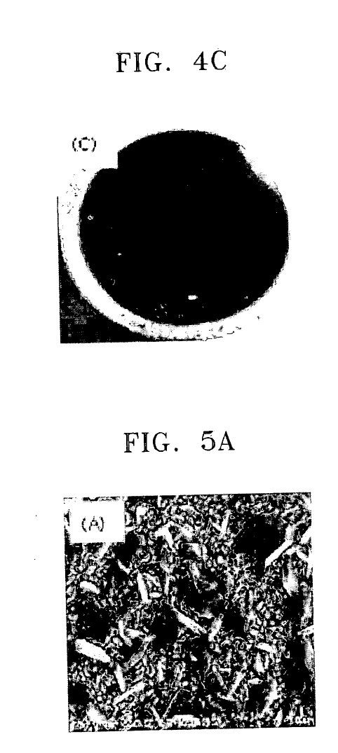

FIGS. 4A through 4C are photographic images of tubes having various surface roughness obtained using various methods. These tubes are coated and the reduced amount of coke was measured. As a result, it is found that when surface roughness decreases, coke formation is more reduced.

In a bare tube shown in FIG. 4A, the amount of coke that was formed as a result of EDC pyrolysis was decreased by 50%. In a tube shown in FIG. 4C, which was pretreated using an electronic polishing method, the amount of coke that was formed as a result of EDC pyrolysis was decreased by 75%.

Due to the coating, the inside of the cracker is more homogenous and is chemically modified. Furthermore, the coated inside of the cracker is microscopically, and physically more homogenous, thereby inhibiting the coke formation.

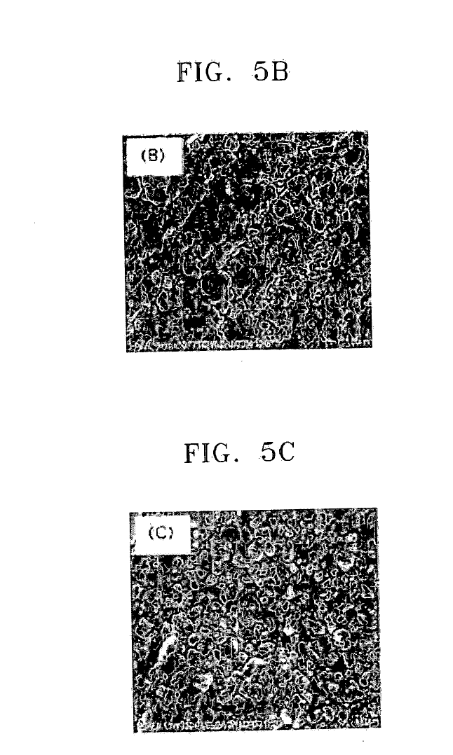

FIG. 5A is a scanning electron microscope (SEM) image of a surface of a SUS-316 sample that was treated with air only. FIG. 5B is a SEM image of a surface of a SUS-316 that was treated with air and steam. FIG. 5C is a SEM image of a surface of a SUS-316 that was treated with the boron compound.

Referring to FIG. 5C, when the inside of the tube was coated with the boron compound, a more homogeneous surface could be attained. Such a structural change in the inner surface results in inhibition of coke formation. However, the major factor that inhibits coke formation is based on a chemical effect of the boron compound coated on the surface of the inside of the tube.

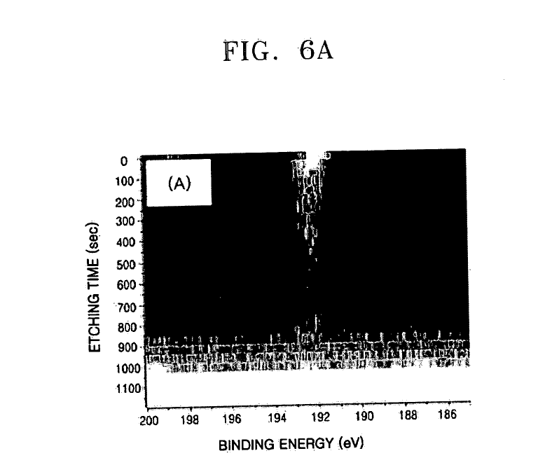

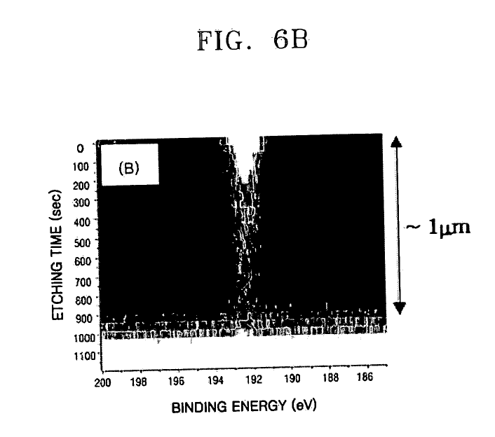

When the coating film was measured using an ESCA method, a 2D depth profile was obtained as shown in FIGS. 6A and 6B, where lighter portions represent stronger electron intensity. Although the original binding energy of boron is 187.7 eV, the binding energy of boron that forms the coating film is increased by 5 eV. In this case, the thickness of the coating film in the cracker was about 1 μm.

When a coating film is formed in an EDC pyrolysis cracker, coke formation in the EDC pyrolysis cracker can be effectively inhibited.

The present invention will be described in further detail with reference to the following examples. These examples are for illustrative purposes only and are not intended to limit the scope of the present invention.

### COMPARATIVE EXAMPLE

A pyrolysis process was performed using a 1-inch SUS-316 cracker having a length of 120 cm that was not pretreated for 20 hours. In this case, a maximum temperature was fixed at 480° C. and a residence time of 99.9% EDC was 18 sec. The amount of coke generated and an EDC conversion were measured. The amount of coke generated was 0.72 g, the EDC conversion was 55%, and by-products were 2.5%. For means of comparison, the amount of coke generated (0.72 g) in the present Comparative Example will be regarded as 100%.

### EXAMPLE 1

A 1-inch SUS-316 cracker having a length of 120 cm was pretreated using a 2 wt % H₃BO₃ solution based on tertiary distilled water and nitrogen at 600° C. In this case, a residence time of the entire flow was 60 sec, a carrier gas was nitrogen, a mole ratio of nitrogen to the boron solution was 3.5, and a coke formation-inhibiting material was coated on the inside of the tube for 5 hours. The supply temperature of the coating material was maintained at 200° C. to prevent precipitation. The coating solution was supplied in droplet. In the coated cracker, EDC pyrolysis was performed for 20 hours at a maximum temperature of 480° C. with a residence time of 99.9% EDC of 18 sec. The amount of coke generated and EDC conversion were measured. As a result, the amount of coke generated was 65% of that in Comparative Example, the EDC conversion was 55% and by-products were 2.5%.

### EXAMPLE 2

Coating conditions were the same as in Example 1, except that the carrier gas was air, the coating temperature was 500° C., and the coating time was 10 hours. In the pretreated cracker, EDC pyrolysis was performed in the same reaction conditions as in Example 1. As a result, the amount of coke generated was 66% of that in Comparative Example, the EDC conversion was 55%, and by-products were 2.7%.

### EXAMPLE 3

Coating conditions were the same as in Example 1, except that the carrier gas was air, the coating temperature was 600° C., and the coating time was 10 hours. In the pretreated cracker, EDC pyrolysis was performed in the same reaction conditions as in Example 1. As a result, the amount of coke generated was 35% of that in Comparative Example, the EDC conversion was 56%, and by-products were 2.4%.

### EXAMPLE 4

Coating conditions were the same as in Example 1, except that the carrier gas was air and the coating was performed using a spray-nozzle method at 600° C. for 5 hours in the cracker. In the pretreated cracker, EDC pyrolysis was performed under the same reaction conditions as in Example 1. As a result, the amount of coke generated was 30% of that in Comparative Example, the EDC conversion was 56%, and by-products were 2.4%.

### EXANPLE 5

Coating conditions were the same as in Example 1, except that the carrier gas was air, the coating was performed using a spray-nozzle method at 600° C. for 5 hours in the cracker, and a mole ratio of air to a boron solution was 10. In the pretreated cracker, EDC pyrolysis was performed in the same reaction conditions as in Example 1. As a result, the amount of coke generated was 75% of that in Comparative Example, the EDC conversion was 55%, and by-products were 2.7%. These results are shown in Table 1.

TABLE 1

| | Amounts of the | | |
|---|---|---|---|
| | coke generated | EDC conversion | By products |
| | (%) | (%) | (In EDC) |
| Comparative | 100 | 55 | 2.5% |
| Example | | | |
| Example 1 | 55 | 55 | 2.5% |
| Example 2 | 66 | 55 | 2.7% |
| Example 3 | 35 | 56 | 2.4% |
| Example 4 | 30 | 56 | 2.4% |
| Example 5 | 75 | 55 | 2.7% |

As identified in Examples 1 through 5 with reference to Table 1, when the pyrolysis reaction was performed after the cracker was treated with a coke formation-inhibiting material according to the present invention, the amount of coke generated was decreased by as much as 70% of that in Comparative Example. Furthermore, the EDC conversion was increased and the selectivity of a VCM that was a final product was not affected. From these results, it was assumed that the formation of a coke precursor and FeCl₃ that is known as a coke formation-inducing material on the surface of a cracker tube was inhibited by the treatment with the coke formation-inhibiting material.

As described above, according to the present invention, a coke formation-inhibiting material is effective for inhibiting coke formation during EDC pyrolysis. When the coke formation-inhibiting material is used, the amount of coke generated is decreased by 50% or greater of the amount of coke generated when the coke formation-inhibiting material is not used. In addition, since the coke formation-inhibiting material does not affect the ECD conversion and the selectivity to a vinyl chloride monomer, the efficiency of the pyrolysis cracker can be maximized. In addition, the decoking cycle of the EDC pyrolyiss cracker can be increased 2 times or greater, and thus, additional VCM can be produced. The coke formation-inhibiting material has a great practical value because it can be collected for re-use and is inexpensive.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A coating film that is formed to reduce the formation of coke in an ethylene dichloride (EDC) pyrolysis cracker, the coating film comprising a boron compound.

2. The coating film of claim 1, wherein the boron compound is a boron compound represented by Formula 1; or a hydrate, oxide, pyrolysis product, oligomer, or sintered product thereof:
(M)ₐ(B)_{b}(X)_{c} Formula 1
where M is a Group IA or IIA metal, or hydrogen;
B is boron;
a and c are each independently an integer of 0-12 where 3≦a+c<24;
b is an integer of 1-10;
when a=0, X is oxygen, hydrogen, halogen, hydroxy, alkoxy, aryloxy, alkyl, aryl, alkylaryl, or arylalkyl; and
when a≧1, X is oxygen.

3. The coating film of claim 2, wherein the boron compound contains at least one compound selected from the group consisting of H₃BO₃, B₂O₃, BF₃, BCl₃, BBr₃, BI₃, BNaO₃, B₂BaO₄, B₄K₂O₇, and B₄Li₂O₇.

4. The coating film of claim 1, wherein an average thickness of the coating film is in the range of 0.01 μm to 10 μm.

5. The coating film of claim 1, wherein the coating film further comprises a phosphine-based compound.

6. The coating film of claim 5, wherein an amount of the phosphine-based compound is in the range of 5-50% by weight based on the weight of the mixture of the boron compound and the phosphine-based compound.

7. The coating film of claim 5, wherein the phosphine-based compound is a phosphine-based compound represented by Formula 2; or a hydrate, oxide, pyrolysis product, oligomer or sintered product thereof;
(P)ₐ(R)_{b} Formula 2
where P is phosphorus;
a is an integer of 1-10;
b is an integer of 3-10; and
R is oxygen, halogen, hydroxy, alkoxy, aryloxy, alkyl, aryl, alkylaryl, or arylalkyl.

8. A method of coating an inside of an ethylene dichloride (EDC) pyrolysis cracker to reduce the coke formation in the ethylene dichloride (EDC) pyrolysis cracker, the method comprising:
feeding a boron compound through a first tube;
feeding a carrier gas through a second tube;
mixing the boron compound and the carrier gas at a junction of the first and second tubes; and
spraying the mixture of the boron compound and the carrier gas through a spray nozzle onto the inside of the ethylene dichloride (EDC) pyrolysis cracker.

9. The method of claim 8, wherein the boron compound is supplied in a form of an aqueous solution having a concentration of 0.5-10% by weight.

10. The method of claim 8, wherein the carrier gas is one of an inert gas, air, and a mixture of these.

11. The method of claim 8, wherein the carrier gas is mixed with the boron compound in a mole ratio of 0.5-10.

12. The method of claim 8, wherein the mixture of the boron compound and the carrier gas is supplied to the inside of the ethylene dichloride pyrolysis cracker at 200-400° C. for 1-24 hours.

13. The method of claim 8, wherein a temperature inside the ethylene dichloride pyrolysis cracker to which the mixture of the boron compound and the carrier gas is supplied ranges from 450° C. to 650° C.

14. The method of claim 8, wherein the mole ratio of the carrier gas to the boron compound is in the range of 2-7, a supply temperature of the mixture of the boron compound and the carrier gas is in the range of 200° C. to 400° C., a temperature inside the ethylene dichloride pyrolysis cracker is in the range of 450° C. to 650° C., supply time of the mixture of the boron compound and the carrier gas is in the range of 1-24 hours, and a residence time of the mixture of the boron compound and the carrier gas in the ethylene dichloride pyrolysis cracker is in the range of 5-100 sec.

15. An ethylene dichloride pyrolysis cracker comprising the coating film of claims 1.
